(19) United States
(12) Patent Application Publication
(10) Pub. No.: US 2017/0320247 A1
(43) Pub. Date: Nov. 9, 2017

(54) COMPOSITE OF METAL MEMBER AND RESIN MOLD, AND METAL MEMBER FOR FORMATION OF COMPOSITE WITH RESIN MOLD

(71) Applicant: FURUKAWA ELECTRIC CO., LTD., Tokyo (JP)

(72) Inventors: Hideki AIZAWA, Tokyo (JP); Shouji KOIZUMI, Tokyo (JP); Michio OOKUBO, Tokyo (JP); Kunio SHIBATA, Nikko-shi (JP); Makoto HASHIMOTO, Nikko-shi (JP)

(73) Assignee: FURUKAWA ELECTRIC CO., LTD., Tokyo (JP)

(21) Appl. No.: 15/656,679

(22) Filed: Jul. 21, 2017

Related U.S. Application Data
(63) Continuation of application No. PCT/JP2016/052056, filed on Jan. 25, 2016.

(30) Foreign Application Priority Data
Jan. 23, 2015 (JP) 2015-011595

(51) Int. Cl. B29C 45/14; B23K 26/352; H01L 23/31; H01L 23/00; H01L 23/495

(52) U.S. Cl. CPC B29C 45/14; B23K 26/352; H01L 23/495; B29K 2995/0072; H01L 23/562; H01L 23/3114

(57) ABSTRACT

A composite including a metal member and a resin mold formed jointed to a surface of the metal member is provided, wherein the metal member has a roughened portion in a joint to the resin mold in the surface, and in a specific interface region including a joint interface between the roughened portion and the resin mold, the average volume in a unit area of voids between the roughened portion and the resin mold is 0.05 μm³ or smaller per 1 μm² of a plane generally parallel to the joint interface, and the maximum dimension of the void is 1000 nm or smaller.

### CROSS REFERENCE TO RELATED APPLICATIONS

This is a continuation application of International Patent Application No. PCT/JP2016/052056 filed Jan. 25, 2016, which claims the benefit of Japanese Patent Application No. 2015-011595, filed Jan. 23, 2015, the full contents of all of which is hereby incorporated by reference in their entirety.

### BACKGROUND

### Technical Field

The present disclosure relates to a composite of a metal member and a resin mold to be used for electronic devices, home electric appliances, parts for vehicles, on-vehicle materials, and so on, and a metal member suitable for formation of such a composite.

### Background

With rapid development of industries including electronics and automobile industries, materials have been increasingly becoming diversified and highly functional. In such a circumstance, in particular, demand for a member including a combination of different materials such as resin and metal, in an efficient manner has been increasing from the viewpoints of reduction in the weight of a part, improvement of the degree of freedom in design, cost reduction, etc.

In the case of a member including a combination of different materials, it is generally difficult to enhance the adhesion of a joint. For example, a semiconductor package structure including a substrate with a molded resin has problems including insufficient attachment between resin and metal particularly at high temperatures and generation of a crack in the resin and peeling off of a chip due to the difference of the coefficient of thermal expansion between the resin and lead frame (metal) or swelling caused by moisture in the package.

To solve the above-mentioned problems, Japanese Laid-Open Patent Publication Nos. 10-294024, 2010-167475, and 2013-111881 each propose a technique to roughen the surface of a metal member to form unevenness particularly in a joint between different materials for enhancement of the adhesion at the joint.

In conventional methods for forming a composite of a metal member and a resin mold, the adhesion strength between metal and resin is insufficient particularly at high temperatures, and molecules of water vapor clusters or the like may permeate the joint interface between metal and resin to deteriorate a functional part in the inside.

The present disclosure is related to providing a composite of a metal member and a resin mold, the composite achieving excellent adhesion between metal and resin and being capable of exerting high airtightness even in use under a high-temperature environment, and a metal member suitable for formation of such a composite.

The present inventors diligently studied, and found that a composite of a metal member and a resin mold in which the metal member has a roughened portion in a joint to the resin mold in the surface, and in a specific interface region including a joint interface between the roughened portion and the resin mold, a void between the roughened portion and the resin mold has a specific average volume in a unit area and a specific maximum dimension achieves excellent adhesion between metal and resin and is capable of exerting high airtightness even in use under a high-temperature environment, and thus completed the present disclosure.

### SUMMARY

Specifically, the configuration summary of the present disclosure is as follows.

[1] A composite including a metal member and a resin mold formed jointed to a surface of the metal member, wherein
the metal member has a roughened portion in a joint to the resin mold in the surface, and
in a specific interface region including a joint interface between the roughened portion and the resin mold,
the average volume in a unit area of voids between the roughened portion and the resin mold is 0.05 μm³ or smaller per 1 μm² of a plane generally parallel to the joint interface, and
the maximum dimension of the void is 1000 nm or smaller.
   [2] The composite of a metal member and a resin mold according to the above [1], wherein the arithmetic average roughness of the roughened portion is 0.13 μm to 100 μm.
   [3] The composite of a metal member and a resin mold according to the above [2], wherein
the metal member has an unroughened region without the roughened portion in a part of the surface, and
the abundance ratio of oxygen in the roughened portion is higher than the abundance ratio of oxygen in the unroughened region.
   [4] The composite of a metal member and a resin mold according to the above [3], wherein the abundance ratio of oxygen element in the roughened portion is 1.3 times or more of the abundance ratio of oxygen in the unroughened region.
   [5] The composite of a metal member and a resin mold according to any one of the above [1] to [4], wherein the roughened portion has a collection of dotted uneven portions.
   [6] The composite of a metal member and a resin mold according to the above [5], wherein the roughened portion includes a region within 100 μm from an outer periphery of each of the dotted uneven portions.

[7] The composite of a metal member and a resin mold according to the above [5] or [6], wherein the depth of each of the dotted uneven portions is 100 nm or more and 50 μm or less.

[8] The composite of a metal member and a resin mold according to any one of the above [5] to [7], wherein the density of the dotted uneven portions is 20 to 2000 portions/mm².
[9] The composite of a metal member and a resin mold according to any one of the above [5] to [8], wherein the diameter of each of the dotted uneven portions is 200 μm or smaller.
[10] The composite of a metal member and a resin mold according to any one of the above [5] to [9], wherein the roughened portion is present in a roughening pattern with the dotted uneven portions continuously disposed.
[11] The composite of a metal member and a resin mold according to any one of the above [5] to [10], wherein
the metal member has a roughened region including the roughened portion in a part of the surface, and
the minimum value of the width of the roughened region is 200 μm or larger.
   [12] The composite of a metal member and a resin mold according to any one of the above [1] to [11], wherein
the composite further includes a functional part in the resin mold, and
the roughened portion is formed in a manner such that the roughened portion at least surrounds the functional part.
   [13] The composite of a metal member and a resin mold according to any one of the above [1] to [12], wherein the composite has a closed space in the resin mold, and the closed space includes a surface of the metal member not covered with the resin mold.
   [14] A metal member including a roughened portion for jointing to a resin mold in a part of the surface to form a composite, wherein
when the resin mold is jointed to the surface of the metal member in a manner such that the resin mold includes the roughened portion,
in a specific interface region including a joint interface between the roughened portion and the resin mold,
the average volume in a unit area of voids between the roughened portion and the resin mold is 0.05 μm³ or smaller per 1 μm² of a plane generally parallel to the joint interface, and the maximum dimension of the void is 1000 nm or smaller.

Through the present disclosure, the present inventors succeeded in providing a composite of a metal member and a resin mold, the composite achieving excellent adhesion between metal and resin and being capable of exerting high airtightness even in use under a high-temperature environment, and a metal member suitable for formation of such a composite.

### BRIEF DESCRIPTION OF DRAWINGS

FIG. 1 is a schematic perspective view of a composite of a metal member and a resin mold according to the present disclosure.

FIG. 2 is a schematic view illustrating the I-I cross-section (X-Y plane) of the composite in FIG. 1.

FIG. 3A is a schematic view illustrating the II-II cross-section (X-Z plane) of the composite in FIG. 1, and FIG. 3B is an enlarged schematic view illustrating a part around a joint between a metal member and a resin mold, where the part is enclosed by a frame in dash-dot lines in FIG. 3A.

FIG. 4 is an enlarged schematic perspective view of the metal member illustrating a part around the joint to the resin mold as an extracted view only of the metal member constituting the composite in FIG. 1.

FIG. 5A is a schematic view for describing a roughened portion formed especially through laser irradiation, and FIG. 5B is a schematic view for describing the relation between a roughened region formed as a collection of a plurality of roughened portions each illustrated in FIG. 5A and an unroughened region.

FIG. 6 is a magnified illustration of roughened portions in a striped pattern.

### DETAILED DESCRIPTION

Hereinafter, embodiments of a composite of a metal member and a resin mold according to the present disclosure will be described in detail.

### <Composite of Metal Member and Resin Mold>

The composite according to the present disclosure is a composite including a metal member and a resin mold formed on a surface of the metal member, wherein the metal member has a roughened portion in a joint to the resin mold in the surface.

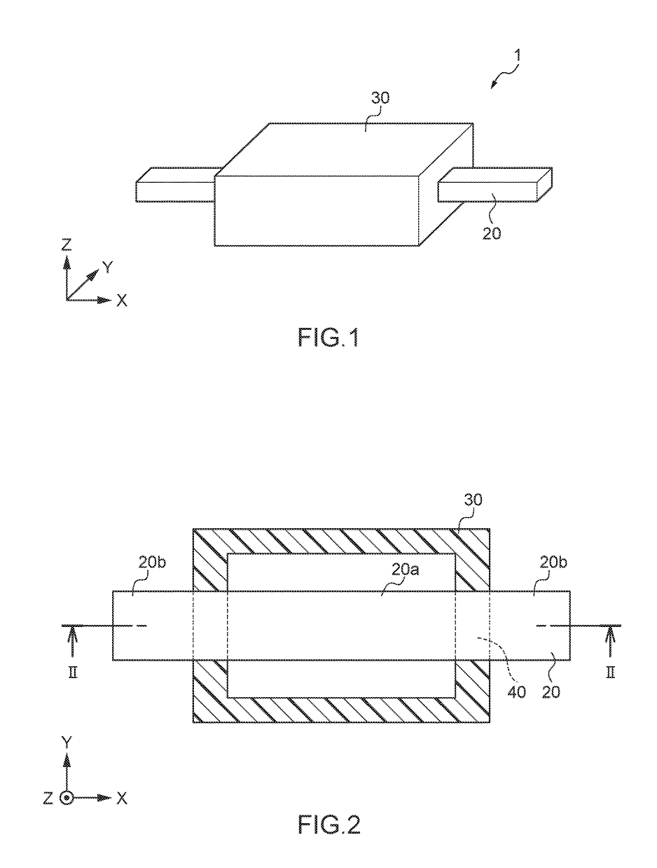

FIG. 1 illustrates one embodiment of the composite according to the present disclosure, and the reference signs 1, 20, and 30 in FIG. 1 indicate the composite, a metal member, and a resin mold, respectively. FIG. 2 is the I-I cross-section (X-Y plane) including a surface of the metal member 20 of the composite illustrated in FIG. 1. In FIG. 2, the reference sign 40 indicates a surface of the metal member 20, which is a joint to the resin mold 30.

As illustrated in FIGS. 1 and 2, the composite 1 according to the present embodiment has a form in which a part of the metal member 20 is embedded in the resin mold 30, and another part is exposed to the outside of the resin mold 30. Then, the metal member 20 has a joint 40 to the resin mold 30 in the surface. The joint 40 is a part of the surface of the metal member 20, and present between a portion embedded in the resin mold 30, 20a, and a portion exposed to the outside, 20b. It follows that the joint 40 corresponds to the portion 40 segmented by dashed lines in a surface of the metal member 20 in FIG. 2. The form of the composite 1 is not limited to the form illustrated in FIGS. 1 and 2, and may be, for example, a form in which the resin mold 30 is attached to one surface of the metal member 20.

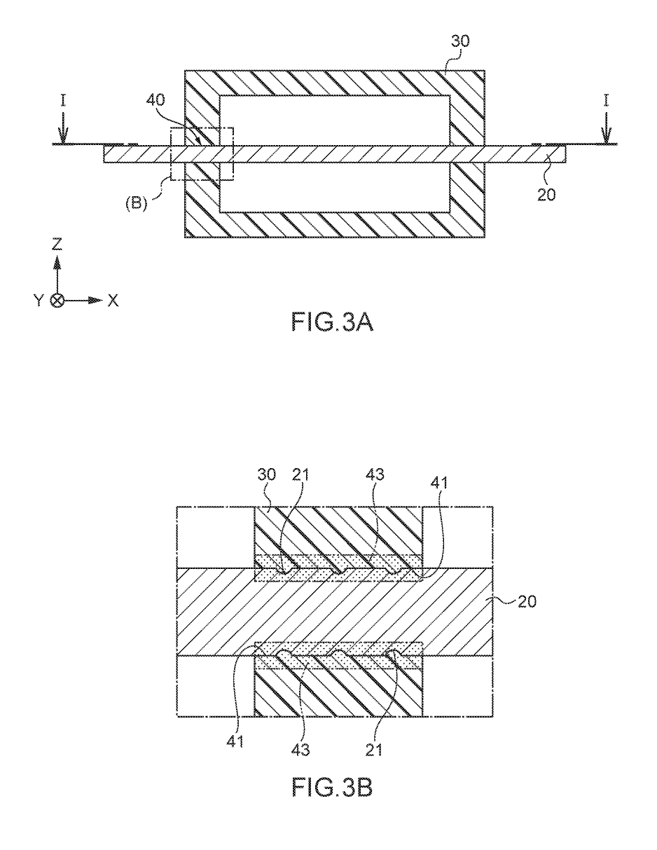

Further, FIG. 3A is the II-II cross-section (X-Z plane) of the composite 1 illustrated in FIG. 1, and furthermore, FIG. 3B is an enlarged view of (B) enclosed by a rectangular frame of dash-dot lines in FIG. 3A. In FIG. 3B, the reference signs 21, 41, and 43 indicate a roughened portion, a joint interface between roughened portions 21 and the resin mold 30, and a specific interface region including a joint interface 41, respectively.

As illustrated in FIG. 3B, the metal member 20 has roughened portions 21 at the joint 40 to the resin mold 30 in the surface. The joint interface 41 is present between the roughened portions 21 of the metal member 20 and the resin mold 30. Here, a specific region including the joint interface 41 is defined as the specific interface region 43. The specific interface region 43 is a region formed to include the joint interface 41 and to have thicknesses in the thickness direction (depth direction) from the position of the joint interface 41 to the resin mold 30 and the metal member 20 including the roughened portions 21, respectively, of approximately 15 μm (each of the regions represented by the dash-dot-dot lines in FIG. 3B).

In such a specific interface region 43, the average volume in a unit area of voids between the roughened portions 21 and the resin mold 30 is 0.05 lams or smaller per 1 μm² of a plane generally parallel to the joint interface 41, and the maximum dimension of the void is 1000 nm or smaller. Through satisfying these relations, the composite according to the present disclosure exerts excellent airtightness between the resin mold and the metal member even in use under a high-temperature environment, and can effectively prevent deterioration of a functional part present in the inside.

Here, when the joint interface, which is uneven, in the specific interface region is regarded as a smooth surface, the plane generally parallel to the joint interface refers to a plane parallel to the smooth surface. Such a plane is also substantially parallel to a surface of the metal member which is present in a plane extended from the joint interface and on which no roughened portions are formed.

The average volume in a unit area of voids is a value calculated by dividing the sum total of the volume of voids by the area of a plane generally parallel to the joint interface between the roughened portions of the metal member and the resin mold to convert to the volume of voids present in 1 μm′ of the plane. The maximum dimension of a void is a maximum value among the longest widths of voids present in the specific interface region. Specific measurement methods for them will be described later in Examples.

Preferably, the composite according to the present disclosure has a closed space in the resin mold, and the closed space includes a metal surface not covered with the resin mold. Such a closed space allows the composite to incorporate a functional part in the inside. Preferably, the composite according to the present disclosure further includes a functional part in the resin mold.

The functional part is characterized in that it is present in a confined space consisting of the resin mold and the metal member. The surface of the functional part may be closely attached to the resin mold or the metal member, or only a part of the surface may be closely attached to the resin mold or the metal member, or the surface may be closely attached to neither the resin mold nor the metal member.

Examples of the functional part include integrated circuits such as microprocessors, microcontrollers, memories, and semiconductor sensors.

Now, components of the composite will be described in detail.

### (Metal Member)

The metal member may be in any shape, for example, a sheet, a wire, a box, a sphere, a shape obtained by bending any of them, or a shape obtained by jointing several of them.

The material of the metal member is not particularly limited, and can be appropriately selected from known metals in accordance with the intended use. Examples of the material of the metal member include metals consisting of one selected from copper, aluminum, iron, titanium, zinc, magnesium, lead, and tin, and alloys containing two or more thereof, and examples of iron alloys include iron-nickel alloy (42 alloy), and stainless steels. A part (e.g., the surface) of the metal member may be plated.

In particular, the metal member is preferably copper or aluminum. In processing with a laser, in general, lasers with a wavelength from visible to near-infrared are relatively accessible, and thus widely used. Hence, copper and aluminum, each of which has high absorbance at a wavelength from visible to near-infrared, are particularly preferred in that they exhibit good processability in laser processing in the wavelength region.

In the case that the metal member is generally sheet-shaped, the thickness is preferably 1 μm to 10 mm, and more preferably 30 μm to 2 mm. If the generally sheet-shaped metal member is thin, the shape is likely distorted when the metal member is partially provided with roughened portions.

The metal member according to the present embodiment has a roughened portion in a joint to the resin mold. This configuration provides good jointing to the resin mold, and high airtightness is achieved when a composite with the resin mold is formed. It is only required that a roughened portion be formed in at least a part of a joint to the resin mold in a surface of the metal member, and a roughened portion may be formed in a part of a joint, or in the whole surface of a joint, or even beyond a joint. From the viewpoint of easiness in treatment after formation of the resin mold (e.g., deburring), it is preferred that no roughened portions be formed in portions not embedded in the resin mold (the portions of the metal member 20 exposed to the outside, 20b, in FIG. 1), and it is preferred that a roughened portion be formed in the whole surface within a joint from the viewpoint of enhancement of the adhesion.

The method for forming a roughened portion as described above is not particularly limited, and a known roughening method which enables formation of unevenness in a part of the surface of the metal member is suitably used. Examples of such known roughening methods include laser irradiation, etching, roughening plating, blasting, and breaking.

The roughened portion refers to a portion of the metal member in which the surface geometry has been modified through treatment to form unevenness in a part of the surface of the metal member. In the case that the roughening method is laser irradiation, for example, the roughened portion is a portion affected by laser irradiation. Particularly in the case of a pulse laser, multiple shots of laser irradiation form a pattern of dotted uneven portions on the metal surface, and thus roughened portions are formed. In this case, a region within 100 μm from the outer periphery of a portion processed with one spot of laser irradiation (spot-irradiated portion: dotted uneven portion) corresponds to the roughened portion. In the case that the roughening method is etching, an etched portion corresponds to the roughened portion. In the case that a metal member such as a lead frame with a thickness of 2 mm or smaller is broken, a broken cross-section with a rough surface corresponds to the roughened portion. Here, a foreign matter attached is not encompassed in the concept of the roughened portion in any of these treatment methods.

The roughened portion includes unevenness formed in a surface of the metal member, and is characterized by the structure allowing a resin to fit to the unevenness to enhance the adhesion.

Preferably, the metal member further has a roughened region including the roughened portion in a part of the surface. The roughened region refers to a region including a roughened portion. In the case of a region with roughened portions continuously disposed, the roughened region and the roughened portions are the same region.

In the case that roughened portions form a discontinuous region such as a zonal pattern, dots, and a marble pattern, the roughened region is a region surrounding the whole of the roughened portions. In this case, the roughened region consists of roughened portions and the other portion (unroughened portion: a portion which has not been roughened). In the case that the minimum distance between roughened portions (length between outer peripheries) is 1000 μm or larger, the respective roughened portions shall be included in different roughened regions (see FIG. 5B).

The surface of the metal member preferably consists of a roughened region including the roughened portion and an unroughened region without the roughened portion. The unroughened region refers to a surface of the metal member excluding the roughened region. That is, the unroughened region does not include any roughened portion obtained through roughening and consists only of unroughened portions.

The arithmetic average roughness (Ra) of the roughened portion is preferably 0.13 μm to 100 μm, and more preferably 0.2 μm to 10 μm. The arithmetic average roughness can be calculated from surface geometry data obtained in measurement with a laser microscope in accordance with a method described in an ISO standard (ISO 25178).

The surface roughness of the metal member has large impact on the permeability of gas which permeates the joint interface between the resin mold and the metal member. Specifically, in the case of large surface roughness, partial peeling, which is caused by a force applied to the joint interface between resin and metal due to the difference of the coefficient of thermal expansion between the resin mold and the metal member or the pressure difference between the inside and the outside, is generated to a larger extent, which facilitates permeation of gas molecules. In the case that the surface roughness of the metal member is small, on the other hand, such partial peeling is generated to a smaller extent, gas molecules or clusters formed of gas molecules are less likely to permeate. However, sufficient adhesion could not be achieved if the surface roughness is excessively small. Hence, from the viewpoints of the size of gas molecules or clusters formed of gas molecule and adhesion, the surface roughness of the metal member is preferably 0.13 μm to 100 μm, and more preferably 0.2 μm to 10 μm, in arithmetic average roughness (Ra). The surface roughness and the arithmetic average roughness as an indicator of the physical property can be appropriately adjusted in accordance with the roughening method or conditions therefor.

The abundance ratio of oxygen in the roughened portion is preferably higher than the abundance ratio of oxygen in the unroughened region. In other words, the abundance ratio of oxygen in the roughened portion is preferably higher than the abundance ratio of oxygen in the unroughened portion. It follows that, in the case that the roughened region includes few unroughened portions and is substantially the same region as the roughened portion, the abundance ratio of oxygen in the roughened region is substantially identical to the abundance ratio of oxygen in the roughened portion, and the abundance ratio of oxygen in the roughened region becomes lower than the abundance ratio of oxygen in the roughened portion as the roughened region includes a larger number of unroughened portions. However, the roughened region is a region including a roughened portion, and hence the abundance ratio of oxygen therein is substantially higher than the abundance ratio of oxygen in the unroughened region. Specific measurement method will be described later in Examples.

The abundance ratio of oxygen in the roughened portion has large impact on the adhesion between the resin mold and the metal member. Specifically, in the case that the abundance ratio of oxygen in the roughened portion is equivalent to or lower than the abundance ratio of oxygen in the unroughened region, it is expected that a resin molten in formation has low wettability, and a void is more likely to be generated in the interface between metal and resin. In the case that the abundance ratio of oxygen in the roughened portion is higher than the abundance ratio of oxygen in the unroughened region, on the other hand, it is expected that the energy generated when a resin molten in formation is oxidized by oxygen present on the metal surface allows the resin to enter fine portions of the roughened structure, and a void is less likely to be generated in the interface between metal and resin. Hence, from the viewpoint of enhancement of the adhesion between the resin mold and the metal member, the abundance ratio of oxygen in the roughened portion is preferably higher than the abundance ratio of oxygen in the unroughened region, and more preferably 1.3 times or more of the abundance ratio of oxygen in the unroughened region.

The abundance ratio of oxygen in the roughened portion can be appropriately adjusted in accordance with conditions for formation of the roughened portion (e.g., the roughening method, conditions therefor, formation density of the roughened portion).

The roughened portion preferably has a collection of dotted uneven portions. In this case, the roughened portion corresponds to a region within 100 μm from the outer periphery of each of the dotted uneven portions. The method for forming such dotted uneven portions is not particularly limited, and such dotted uneven portions can be formed, for example, through laser irradiation or the like.

The depth of each of the dotted uneven portions is preferably 100 nm or more, and more preferably 500 nm or more, from the viewpoint of achievement of sufficient adhesion strength. From the viewpoints of suppression of the strain of the metal part and prevention of deterioration of the metal due to oxidation, the depth of each of the dotted uneven portions is preferably 50 μm or less, more preferably 20 μm or less, and even more preferably 10 μm or less.

The density of the dotted uneven portions is preferably 20 to 2000 portions/mm², and more preferably 50 to 1000 portions/mm², from the viewpoints of suppression of the strain of the metal member and prevention of deterioration due to oxidation.

The diameter of each of the dotted uneven portions is preferably 200 μm or smaller, more preferably 100 μm or smaller, and even more preferably 50 μm or smaller, from the viewpoint of formation of unevenness with fine geometry.

A roughened portion is defined as a region within 100 μm from the outer periphery of one dotted uneven portion. Hence, in the case that a roughened portion has a collection of dotted uneven portions, one roughened portion formed of one dotted uneven portion preferably overlaps with another roughened portion formed of another dotted uneven portion, and more preferably such roughened portions continuously overlap with each other. The airtightness can be ensured more reliably through continuous roughened portions. It is preferred that such roughened portions be present in a roughening pattern in which roughened portions each formed of an independent dotted uneven portion continuously overlap with each other. Specifically, it is more preferred that roughened portions be present in a roughening pattern with dotted uneven portions continuously disposed.

The geometry of the roughening pattern is not particularly limited, and examples thereof include zonal patterns and striped patterns. Such a roughening pattern is preferably formed along the joint to the resin mold, and may be formed generally in parallel with the planar boundary with the resin mold formed on the metal member. In the case that a functional part is disposed in the inner space of the resin mold, such a roughening pattern is preferably formed such that the roughening pattern at least surrounds the functional part.

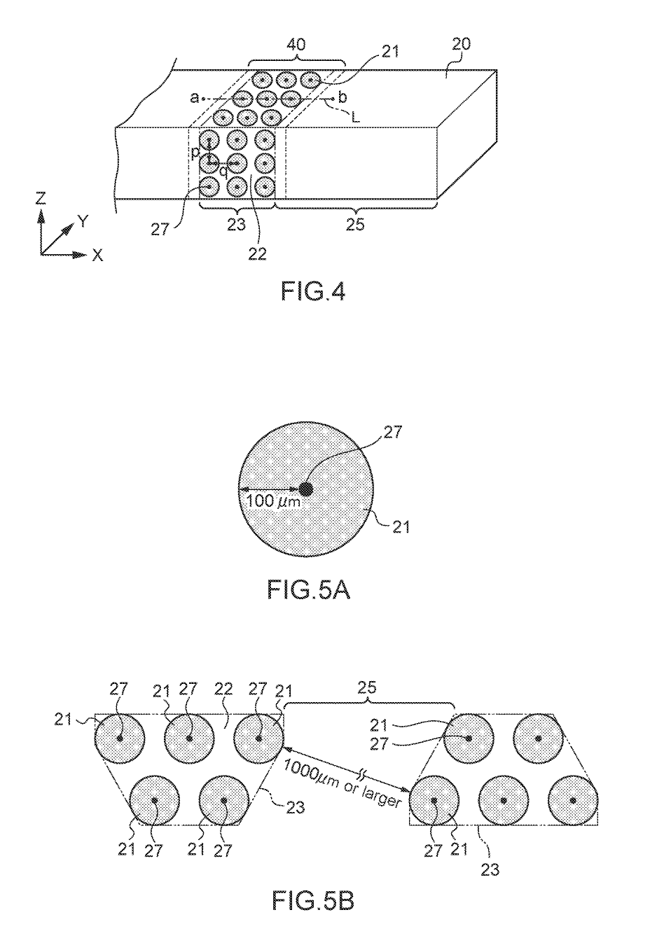

In the case that the roughened portion is present in the roughening pattern, the minimum value of the width of the roughened region is preferably 200 μm or larger, and more preferably 500 μm or larger. As the minimum value of the width of the roughened region becomes larger, the amount of water vapor molecules or the like which permeate the joint interface between resin and metal can be reduced more successfully. Here, the minimum value of the width of the roughened region refers to the length of the roughened region on the line L crossing, in the shortest distance, the joint to the resin mold in the surface of the metal member (the line in the surface of the metal member between the point a in the inside of the resin mold and the point b exposed to the outside of the resin mold, see FIG. 4). Further, the length of a part of the line L in which roughened portions are continuously present is preferably 200 μm or larger, and more preferably 500 μm or larger.

In the case that a part of the metal member is plated, the roughened portion may be present in a plated portion, or may be present in a portion of exposed base, or may be present over a plated portion and a portion of exposed base.

As described above, the method for forming a roughened portion is not limited. For partial roughening as described above, however, roughening methods with a laser are preferred. Now, a roughening method with a laser will be described as an example with reference to FIGS. 4 to 6.

For the laser, a CW (continuous wave) laser or a pulse laser can be used. In the case that a pulse laser is used, for example, a collection of dotted uneven portions can be easily formed through formation of a pattern of processed portions on the metal surface by multiple shots of laser irradiation (portions spot-irradiated with a laser). By further combining such collections, a pattern of repeated stripes can be formed.

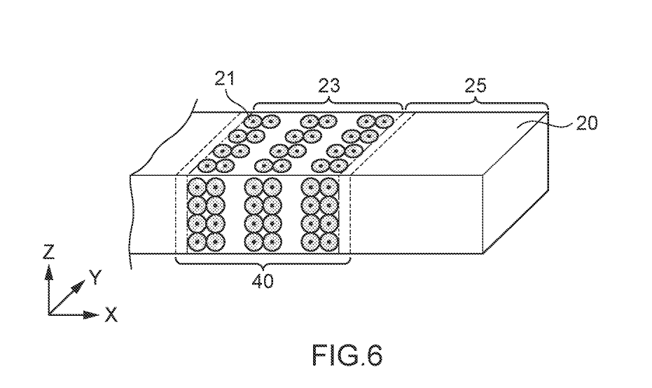

FIG. 4 is an enlarged schematic view illustrating of the joint 40 to the resin mold 30 as an extracted view only of the metal member 20 in the composite 1 in FIG. 1. In FIG. 4, the reference signs 22, 23, 25, and 27 indicate an unroughened portion, a roughened region, an unroughened region, and a portion spot-irradiated with a laser, respectively. FIG. 5A is a schematic view especially illustrating the relation between the spot-irradiated portion 27 and the roughened portion 21, and FIG. 5B is a schematic view especially illustrating the relation among the roughened portions 21, the unroughened portion 22, the roughened regions 23, and the unroughened region 25. FIG. 6 is a schematic view in the case that roughened portions are formed in a roughening pattern of repeated stripes.

FIG. 4 shows the metal member in which a collection of dotted uneven portions is formed in the joint 40 to the resin mold 30 through laser irradiation with a pulse laser. Here, the roughened portion 21 is, as illustrated in FIG. 5A, a region within 100 μm from the outer periphery of a portion processed with one spot of laser irradiation (spot-irradiated portion: dotted uneven portion). Such a roughened portion may overlap with another roughened portion to form continuous roughened portions, or two or more roughened portions may be formed at intervals without overlapping.

Further, in the case that a roughened region 23 includes, for example, two or more roughened portions 21 as illustrated in FIG. 5B, the roughened region 23 corresponds to a region segmented by a polygon having the minimum area among polygons inscribing the outer peripheries of outermost roughened portions 21 among the roughened portions 21 included in the joint 40. It is preferred that roughened portions 21 adjacent to each other in the roughened region 23 be positioned at an interval of 500 μm or less between the outer peripheries of them. If the outer peripheries of roughened portions 21 proximate to each other are separated by 1000 μm or more, the region therebetween shall be excluded from the roughened region 23 (defined as the unroughened region 25).

In the case of a pulse laser, a pulse width in the order of 0.1 picoseconds to 1 millisecond can be preferably used from the viewpoint of achievement of the above-described geometry through processing. Energy per pulse of 10 μJ to 1000 μJ can be preferably used.

The spot diameter is preferably 200 μm or smaller, more preferably 100 μm or smaller, and even more preferably 50 μm or smaller, from the viewpoints of higher energy density and formation of unevenness with fine geometry. From the viewpoint of condensation of laser light, the spot diameter is preferably 20 μm or larger.

The density of spot irradiation is preferably 20 spots/mm² or higher, more preferably 50 spots/mm² or higher, and even more preferably 100 spots/mm² or higher. From the viewpoints of suppression of the strain of the metal member, prevention of generation of scattered debris, and prevention of degradation due to oxidation, the density of spot irradiation is preferably 2000 spots/mm² or lower, more preferably 1000 spots/mm² or lower, and even more preferably 500 spots/mm² or lower.

The energy density per spot is preferably 1 to 50 J/cm². Here, the energy density is a value calculated by dividing pulse energy by the area of a spot-irradiated portion. If the energy density is lower than 1 J/cm², processing cannot be performed sufficiently. If the energy density is higher than 50 J/cm², metals molten or broken by laser irradiation are scattered and attached therearound. Since these attached matters lower the bonding force in wire bonding, for example, generation of attached matters is not preferred.

A wavelength of 300 nm to 20000 nm can be preferably used. In the case of copper or aluminum, for example, a laser with a wavelength of approximately 300 nm to 600 nm, at which copper or aluminum exhibits high absorbance, is preferably used.

The arithmetic average roughness and oxygen concentration of the roughened portion can be appropriately adjusted in accordance with the roughening method, and can be appropriately adjusted, for example, through adjustment of the laser output, spot diameter, spot distribution including spot intervals (p, q in FIG. 4), and so on, in laser irradiation.

### (Resin Mold)

The resin mold according to the present embodiment is a member of a resin material formed at least in a part of the surface of the metal member.

The resin material is not particularly limited as long as it is a material which can be jointed at a temperature lower than the melting point of the metal material, and examples thereof include thermoplastic resins, thermosetting resins, elastomers, and plastic alloys. Alternatively, the resin material may be a material curable through a non-thermal means, for example, a material curable through non-thermal energy such as a photocurable resin, or a material chemically curable through blendinvoidlurality of components together.

More specifically, examples of thermoplastic resins (general-purpose resins) include polyethylene (PE), polypropylene (PP), polystyrene (PS), acrylonitrile/styrene resin (AS), acrylonitrile/butadiene/styrene resin (ABS), methacrylic resin (PMMA), and polyvinyl chloride (PVC).

Examples of thermoplastic resins (general-purpose engineering resins) include polyamide (PA), polyacetal (POM), ultra-high-molecular-weight polyethylene (UHPE), polybutylene terephthalate (PBT), GF-reinforced polyethylene terephthalate (GF-PET), polymethylpentene (TPX), polycarbonate (PC), and modified polyphenylene ether (PPE).

Examples of thermoplastic resins (super engineering resins) include polyphenylene sulfide (PPS), polyether ether ketone (PEEK), liquid crystal polymer (LCP), polytetrafluoroethylene (PTFE), polyetherimide (PEI), polyarylate (PAR), polysulfone (PSF), polyethersulfone (PES), and polyamideimide (PAT).

Examples of thermosetting resins include phenolic resin, urea resins, melamine resins, unsaturated polyester, alkyd resins, epoxy resins, and diallyl phthalate.

Examples of elastomers include thermoplastic elastomers and rubbers such as styrene-butadiene rubbers, polyolefin rubbers, urethane rubbers, polyester rubbers, polyamide rubbers, 1,2-polybutadiene, polyvinyl chloride rubbers, and ionomers.

Further examples include thermoplastic resins with a glass fiber and polymer alloys. In addition, any conventionally known additive which does not deteriorate the airtightness may be contained, such as various inorganic and organic fillers, flame retardants, UV absorbers, thermal stabilizers, light stabilizers, colorants, carbon black, release agents, and plasticizers.

In such a thermoplastic resin, thermosetting resin, or thermoplastic elastomer, a known fibrous filler can be blended. Examples of known fibrous fillers include carbon fibers, inorganic fibers, metal fibers, and organic fibers.

More specifically, a well-known carbon fiber such as PAN-based, pitch-based, rayon-based, and lignin-based carbon fibers can be used.

Examples of inorganic fibers include glass fibers, basalt fibers, silica fibers, silica-alumina fibers, zirconia fibers, boron nitride fibers, and silicon nitride fibers.

Examples of metal fibers include fibers formed of stainless steel, aluminum, copper, or the like.

Examples of applicable organic fibers include synthetic fibers such as polyamide fibers (totally-aromatic polyamide fibers or semi-aromatic polyamide fibers including a diamine and a dicarboxylic acid as an aromatic compound, aliphatic polyamide fibers), polyvinyl alcohol fibers, acrylic fibers, polyolefin fibers, polyoxymethylene fibers, polytetrafluoroethylene fibers, polyester fibers (including totally-aromatic polyester fibers), polyphenylene sulfide fibers, polyimide fibers, and liquid crystal polyester fibers; natural fibers (e.g., cellulose-based fibers); and regenerated cellulose (rayon) fibers.

In jointing the resin mold to the metal material, jointing is preferably performed through well-known injection molding. Such injection molding may be either outsert molding or insert molding. In addition, methods of thermal fusion, application of a varnish, potting, and so on are also applicable.

Hereinbefore, embodiments of the present disclosure have been described. However, the present disclosure is never limited to the above embodiments, and includes all aspects included in the concept of the present disclosure and appended claims, and various modifications can be made within the scope of the present disclosure.

The composite according to the present disclosure is excellent in adhesion between the resin mold and the metal member, and thus can be suitably used for applications requiring retention of an airtight state in the inside or applications requiring adhesion between the metal member and the resin mold. For example, the composite according to the present disclosure is suitable for a composite molded body including an electric/electronic part susceptible to humidity or moisture in the inside. In particular, the composite according to the present disclosure is preferably used as a part of an electric or electronic device which may break down by the intrusion of moisture or humidity and for which use in a field requiring waterproofness at a high level, such as a river, a pool, a ski resort, and a bath, is contemplated. For example, the composite according to the present disclosure is useful for housings for electric/electronic devices including a boss made of resin and a holding member in the inside. Examples of housings for electric/electronic devices include, in addition to housings for a cell phone, housings for a portable video electronic device such as a camera, a video-integrated camera, and a digital camera; housings for a portable information terminal or communication terminal such as a laptop computer, a pocket computer, a calculator, an electronic diary, a PDC, and a PHS; housings for a portable acoustic electronic device such as an MD, a headphone stereo cassette player, and a radio; and housings for a home electric appliance such as a liquid crystal TV/monitor, a telephone, a facsimile, and a hand scanner. The composite according to the present disclosure is excellent in adhesion in use under a high-temperature environment, and thus can be preferably used for a part or the like to be used under a high-temperature environment. Examples thereof include automobile parts.

### EXAMPLES

Next, Examples and Comparative Examples will be described in detail to further clarify the advantageous effects of the present disclosure. However, the present disclosure is never limited to these Examples.

### Examples 1 to 7 and Comparative Examples 1 to 5

A copper sheet of 20 mm×70 mm×2 mm was prepared, and roughened portions were formed on the surface of the copper sheet with a laser. The conditions for laser irradiation were as follows.

For the laser, an MD-V9600A (manufactured by KEYENCE CORPORATION) was used. The spot diameter and spot interval p were as shown in Table 1, and the spot interval q was set at 200 μm, the number of spot lines was set at three (the pattern illustrated in FIG. 4), and the width of the roughened region was set at 630 μm.

The spot intervals (p, q) are in accordance with those in FIG. 4. Specifically, the spot intervals (p, q) are each the direct distance between the centers of spot-irradiated portions adjacent to each other.

The positions at which roughened portions were formed were set within an area for a joint to a resin mold, as illustrated in FIG. 4.

The copper sheet on which roughened portions had been formed was subjected to insert molding with a polyamide resin (CM3001G-30, manufactured by Toray Industries, Inc.) into a box of 30 mm×50 mm×20 mm with a resin thickness of 1.5 mm, and thus a composite as illustrated in FIG. 1 was obtained. Jointing of the copper sheet and the resin was achieved at the roughened portions formed on the surface of the copper sheet.

<Evaluation>

Each of the composites in the above Examples and Comparative Examples was subjected to measurement and evaluation shown below. Conditions for evaluation were as follows. The results are shown in Table 1.

[Observation of Void]

(1) First, for each of the composites in Examples and Comparative Examples, a portion around the joint between the metal member and the resin mold was cut with a focused ion beam (FIB) to reveal the cross-section perpendicular to the joint interface between the resin mold and the metal member, as illustrated in FIGS. 3A and 3B. Next, an area of 30 μm×30 μm including the joint interface between the roughened portions and the resin mold in the revealed cross-section was observed with a scanning electron microscope (SEM). Although the length of the edge of the observation area parallel to the joint interface was set at 30 μm, the length of the edge can be suitably regulated within the length in the direction parallel to the joint interface of roughened portions to be observed.
(2) Subsequently, a new cross-section was revealed by cutting by 100 nm in the direction perpendicular to the observation area (in the depth direction to the above cross-section) with an FIB, and an area of 30 μm×30 μm including the joint interface between the roughened portions and the resin mold was observed with an SEM in the same manner as in (1).
(3) Thereafter, the operation of (2) was further repeated 28 times.
(4) Next, SEM images (30 images) of the area of 30 μm×30 μm including the joint interface between the roughened portions and the resin mold, which had been taken in SEM observation in (1) to (3), were used to construct a three-dimensional stereoscopic view (height 30×width 30×depth 3 μm) around the joint interface between the roughened portions and the resin mold.
(5) Further, (1) to (4) were performed for 10 arbitrarily selected sites in the joint interface between the roughened portions of the metal member and the resin mold to produce 10 three-dimensional stereoscopic views in total.
(6) From each of the three-dimensional stereoscopic views obtained, the dimension of each void (the largest distance therein) included in the three-dimensional stereoscopic view was measured, and the dimension of the largest void in the three-dimensional stereoscopic view was evaluated. Evaluation of the dimension of the largest void was performed for the three-dimensional stereoscopic views of the 10 arbitrarily selected sites, and the largest value was used as the maximum dimension. The results are shown in Table 1.
(7) The summation of the volumes of voids included in each three-dimensional stereoscopic view was divided by the area of a plane generally parallel to the joint interface in the stereoscopic object in the measurement area (here, 30 μm×3 μm=90 μm²) to calculate the volume of voids present in 1 μm² of a plane generally parallel to the joint interface. This measurement was performed for 10 different roughened portions to calculate the average value. The results are shown in Table 1.

[Arithmetic Average Roughness]

By using a laser microscope (VK-X250, manufactured by KEYENCE CORPORATION), the arithmetic average roughness (Ra) according to an ISO standard (ISO 25178) was measured for the roughened portions formed on the surface of the metal member. A magnification of 1000× and a cutoff value of 80 μm were used for the conditions for measurement with the laser microscope, and measurement was performed for a rectangle area of 500 μm×350 μm. The arithmetic average roughness was similarly measured for 10 arbitrarily selected roughened portions, and the average value (N=10) was used as the arithmetic average roughness of the roughened portions in this test. For the metal member in Comparative Example 1, no roughened portions were formed thereon, and hence this measurement was performed for a surface of the metal member corresponding to a joint. A correlation has been found between the arithmetic average roughness of the roughened portions of the metal member before formation of the resin mold and the arithmetic average roughness of the roughened portions after formation of the resin mold when the cross-section of the specific interface region is observed.

[Abundance Ratio of Oxygen]

The abundance of oxygen element in a region from the metal surface to the depth of 10 μm was evaluated by using an electron probe microanalyzer (EPMA). For the apparatus, a JXA8800RL (manufactured by JEOL Ltd.) was used.

(1) First, an area in which the arithmetic average roughness was within 0.10 μm to 100 μm was selected for measurement from around the joint between the metal member and the resin mold for each of the composites in Examples and Comparative Examples, and cut out with an FIB to reveal a cross-section perpendicular to the joint interface between the resin mold and the metal member as illustrated in FIGS. 3A and 3B.

(2) Next, mapping of the intensity of the O-Kα line was performed at an accelerating voltage of 15 kV for an area of 100 μm square of the roughened portions in the revealed cross-section such that a region from the metal surface to the depth of 10 μm of the metal member was included. From the resulting mapping data, the average value of the intensity of the O-Kα line in the region from the metal surface to the depth of 10 μm of the metal member was calculated.

(3) (2) was performed for 10 arbitrarily selected sites including a roughened portion, and the average value of the intensity of the O-Kα line was calculated for each of the 10 sites. The average values for the 10 arbitrarily selected sites were further averaged to calculate the average intensity of the O-Kα line at the roughened portions (N=10).

(4) Subsequently, the measurements of (2) and (3) were performed for 10 arbitrarily selected sites in a part without a roughened portion (unroughened region) in the revealed cross-section to calculate the average intensity of the O-Kα line at the unroughened region without a roughened portion (N=10).

(5) From the average intensity of the O-Kα line at the roughened portions and that at the unroughened region obtained through (1) to (4), the intensity ratio of the roughened portions to the unroughened region (roughened portions/unroughened region) was calculated. The results are shown in Table 1.

[Airtightness Test (Pressure Loss)]

First, each of the composites in Examples and Comparative Examples was punctured and a tube was inserted from the hole, and the inside of the composite was pressurized with compressed air at 100 kPa, and pressure loss after 1 minute was measured. The measurement was performed under two types of environments: at normal temperature and at high temperature (60° C.).

For the measurement of pressure, a fine pressure difference gauge (DP gauge MODEL DP-330BA, manufactured by COSMO INSTRUMENTS CO., LTD.) was used. The measurement was performed at N=3 for each sample, and the measured values were averaged, and the average value was used as the pressure loss value (Pa) of each sample.

In Examples, a pressure loss value of 750 Pa or lower was rated as good, and 500 Pa or lower was rated as particularly good at normal temperature. At high temperature (60° C.), 1500 Pa or lower was rated as good, and 1000 Pa or lower was rated as particularly good.

TABLE 1

| | | | | | Roughened | | | |
|---|---|---|---|---|---|---|---|---|
| | Conditions for laser | | | | portions (joints) | Abundance ratio | Pressure loss value | |
| | irradiation | | Voids | | Arithmetic | of oxygen | | High |
| | Spot | | Maximum | Average volume | average | Roughened portions/ | Room | temperature |
| | diameter | Interval: p | dimension | in unit area | roughness | unroughened | temperature | (60° C.) |
| | (μm) | (μm) | (nm) | (μm³/μm²) | Ra (μm) | region | (Pa) | (Pa) |
| Example 1 | 30 | 20 | 85 | 0.016 | 2.10 | 4.1 | 42 | 50 |
| Example 2 | 30 | 50 | 154 | 0.018 | 0.83 | 2.3 | 97 | 145 |
| Example 3 | 30 | 100 | 198 | 0.022 | 0.46 | 1.9 | 187 | 291 |
| Example 4 | 30 | 200 | 272 | 0.035 | 0.22 | 1.4 | 389 | 765 |
| Example 5 | 30 | 500 | 410 | 0.042 | 0.13 | 1.4 | 495 | 1310 |
| Example 6 | 60 | 50 | 355 | 0.029 | 0.18 | 2.3 | 422 | 1012 |
| Example 7 | 90 | 20 | 228 | 0.033 | 0.21 | 4.3 | 443 | 794 |
| Comparative Example 1 | untreated | | 8478 | 4.300 | 0.11 | — | 1133 | 2035 |
| Comparative Example 2 | 60 | 200 | 871 | 0.120 | 0.11 | 1.3 | 798 | 1781 |
| Comparative Example 3 | 90 | 50 | 524 | 0.062 | 0.21 | 1.2 | 721 | 1562 |
| Comparative Example 4 | 250 | 20 | 1480 | 0.170 | 0.11 | 1.1 | 1098 | 2004 |
| Comparative Example 5 | 45 | 300 | 711 | 0.090 | 0.11 | 1.1 | 806 | 1754 |

*In the table, bold characters with an underline indicate that the value is out of the proper range of the present disclosure or the evaluation result is below the acceptable level in Examples.

As shown in Table 1, it was found that the composites in Examples 1 to 7, in each of which, in particular, the average volume in a unit area and maximum dimension of the voids between the roughened portions and the resin mold were each in a particular range, exhibited a small pressure loss value, and thus were excellent in airtightness.

In contrast, it was found that the composite in Comparative Example 1, in which no roughened portions were formed, and the composites in Comparative Examples 2 to 5, in each of which at least one of the average volume in a unit area and maximum dimension of the voids between the roughened portions and the resin mold was out of a particular range, exhibited a large pressure loss value particularly at high temperature, and thus were poor in airtightness in comparison with the composite according to the present disclosure.

### Examples 8 to 13

In each of Examples 8 to 13, a composite was produced and evaluated in the same manner as in Example 1 except that the material of the metal member, the type of a resin, the spot intervals (p, q), the number of spot lines, and the width of the roughened region were changed as shown in Table 2. The conditions and evaluation results are shown in Tables 2 and 3. In Tables 2 and 3, Example 1 is the same as that shown in Table 1.

In Table 2, copper, aluminum, PA, and PBT indicate the above copper sheet, an aluminum sheet of 20 mm×70 mm×2 mm, the above polyamide resin, and a polybutylene terephthalate resin (1101G-X54, manufactured by Toray Industries, Inc.), respectively.

TABLE 2

| | | | Conditions for laser irradiation | | | | |
|---|---|---|---|---|---|---|---|
| | Material | | Spot | | | Number of | Width of roughened |
| | Metal | Resin | diameter | Interval: p | Interval: q | spot lines | region |
| | member | mold | (μm) | (μm) | (μm) | (lines) | (μm) |
| Example 1 | copper | PA | 30 | 20 | 200 | 3 | 630 |
| Example 8 | copper | PBT | 30 | 20 | 200 | 3 | 630 |
| Example 9 | aluminum | PA | 30 | 20 | 200 | 3 | 630 |
| Example 10 | aluminum | PBT | 30 | 20 | 200 | 3 | 630 |
| Example 11 | copper | PA | 30 | 50 | 200 | 5 | 1030 |
| Example 12 | copper | PA | 30 | 50 | 200 | 10 | 2030 |
| Example 13 | copper | PA | 30 | 50 | 200 | 1 | 230 |

TABLE 3

| | | | Roughened | Abundance ratio | | |
|---|---|---|---|---|---|---|
| | Voids | | portions | of oxygen | Pressure loss value | |
| | | Average | Arithmetic | Roughened | | High |
| | Maximum | volume | average | portions/ | Room | temperature |
| | dimension | in unit area | roughness | unroughened | temperature | (60° C.) |
| | (nm) | (μm³/μm²) | Ra(μm) | region | (Pa) | (Pa) |
| Example 1 | 85 | 0.016 | 2.10 | 4.1 | 42 | 50 |
| Example 8 | 127 | 0.017 | 2.10 | 4.1 | 35 | 44 |
| Example 9 | 138 | 0.016 | 3.80 | 6.4 | 36 | 41 |
| Example 10 | 155 | 0.018 | 3.80 | 6.4 | 33 | 38 |
| Example 11 | 162 | 0.026 | 0.91 | 2.7 | 53 | 74 |
| Example 12 | 156 | 0.023 | 0.94 | 2.7 | 22 | 32 |
| Example 13 | 208 | 0.028 | 0.70 | 2.7 | 722 | 1152 |

As shown in Tables 2 and 3, it was found that a composite in which, in particular, the average volume in a unit area and maximum dimension of the voids between the roughened portions and the resin mold were each in a particular range exhibited a small pressure loss value, and thus was excellent in airtightness, even when any of the material of the metal member, the resin material constituting the resin mold, the spot interval p and the number of spot lines in laser irradiation, and the width of the roughened region was changed.

### Examples 14 to 19

In each of Examples 14 to 19, a composite was produced and evaluated in the same manner as in Example 1 except that a JenLas fiber ns 20-advanced (manufactured by JENOPTIK AG) was used as a laser, the pulse energy was set at 500 and the spot intervals (p, q) were changed as shown in Table 4. The conditions and evaluation results are shown in Tables 4 and 5.

In each of Examples 14 to 19, the spot depth, the spot density, and the presence or absence of strain and scattered debris were checked for the copper sheet on which roughened portions were formed. The spot depth (depth of unevenness) was measured with a laser microscope (VK-X250, manufactured by KEYENCE CORPORATION). The spot density was the number of spots counted per unit area (mm²). The presence or absence of strain was determined through visual observation around the roughened portions, and the presence or absence of scattered debris was determined through optical microscopic observation particularly around the laser spots.

TABLE 4

| | Conditions for | | | | | |
|---|---|---|---|---|---|---|
| | laser irradiation | | States of portions subjected to laser irradiation | | | |
| | Interval: p | Interval: q | Depth | Spot density | | |
| | (μm) | (μm) | (μm) | spots/mm² | Strain | Scattered debris |
| Example 14 | 100 | 200 | 8 | 50 | absent | absent |
| Example 15 | 20 | 200 | 13 | 250 | absent | very small amount |
| Example 16 | 5 | 200 | 32 | 1000 | absent | very small amount |
| Example 17 | 20 | 40 | 14 | 1250 | absent | very small amount |
| Example 18 | 5 | 80 | 35 | 2500 | present | very small amount |
| Example 19 | 2 | 400 | 68 | 1250 | present | large amount |

TABLE 5

| | | | Roughened | Abundance ratio | | |
|---|---|---|---|---|---|---|
| | Voids | | portions | of oxygen | Pressure loss value | |
| | | Average | Arithmetic | Roughened | | High |
| | Maximum | volume | average | portions/ | Room | temperature |
| | dimension | in unit area | roughness | unroughened | temperature | (60° C.) |
| | (nm) | (μm³/μm²) | Ra(μm) | region | (Pa) | (Pa) |
| Example 14 | 182 | 0.024 | 0.41 | 1.7 | 231 | 284 |
| Example 15 | 98 | 0.015 | 2.00 | 4.2 | 45 | 63 |
| Example 16 | 88 | 0.012 | 8.50 | 13.5 | 12 | 15 |
| Example 17 | 85 | 0.012 | 11.40 | 15.2 | 8 | 12 |
| Example 18 | 81 | 0.013 | 19.20 | 30.4 | 4 | 6 |
| Example 19 | 87 | 0.014 | 10.50 | 16.5 | 7 | 12 |

As shown in Tables 4 and 5, it was found that, a composite in which, in particular, the average volume in a unit area and maximum dimension of the voids between the roughened portions and the resin mold were each in a particular range exhibited a small pressure loss value, and thus was excellent in airtightness, even when any of the apparatus for laser irradiation, the spot intervals (p, q), the spot depth, and the spot density was changed.

In addition, it was found that the conditions as shown in Table 4 provided a metal member with less strain and fewer scattered debris. Strain does not become a problem as long as a metal member with a large thickness is selected.

What is claimed is:

1. A composite comprising a metal member and a resin mold formed jointed to a surface of the metal member, wherein
the metal member has a roughened portion in a joint to the resin mold in the surface, and
in a specific interface region including a joint interface between the roughened portion and the resin mold,
an average volume in a unit area of a void between the roughened portion and the resin mold is 0.05 μm³ or smaller per 1 μm² of a plane generally parallel to the joint interface, and
a maximum dimension of the void is 1000 nm or smaller.

2. The composite of a metal member and a resin mold according to claim 1, wherein an arithmetic average roughness of the roughened portion is 0.13 μm to 100 μm.

3. The composite of a metal member and a resin mold according to claim 2, wherein
the metal member has an unroughened region without the roughened portion in a part of the surface, and
an abundance ratio of oxygen in the roughened portion is higher than an abundance ratio of oxygen in the unroughened region.

4. The composite of a metal member and a resin mold according to claim 3, wherein the abundance ratio of oxygen element in the roughened portion is 1.3 times or more of an abundance ratio of oxygen in the unroughened region.

5. The composite of a metal member and a resin mold according to claim 1, wherein the roughened portion has a collection of dotted uneven portions.

6. The composite of a metal member and a resin mold according to claim 5, wherein the roughened portion includes a region within 100 μm from an outer periphery of each of the dotted uneven portions.

7. The composite of a metal member and a resin mold according to claim 5, wherein a depth of each of the dotted uneven portions is 100 nm or more and 50 μm or less.

8. The composite of a metal member and a resin mold according to claim 5, wherein a density of the dotted uneven portions is 20 to 2000 portions/mm².

9. The composite of a metal member and a resin mold according to claim 5, wherein a diameter of each of the dotted uneven portions is 200 μm or smaller.

10. The composite of a metal member and a resin mold according to claim 5, wherein the roughened portion is present in a roughening pattern with the dotted uneven portions continuously disposed.

11. The composite of a metal member and a resin mold according to claim 5, wherein
the metal member has a roughened region including the roughened portion in a part of the surface, and
a minimum value of a width of the roughened region is 200 μm or larger.

12. The composite of a metal member and a resin mold according to claim 1, wherein
the composite further includes a functional part in the resin mold, and
the roughened portion is formed in a manner such that the roughened portion at least surrounds the functional part.

13. The composite of a metal member and a resin mold according to claim 1, wherein the composite has a closed space in the resin mold, and the closed space includes a surface of the metal member not covered with the resin mold.

14. A metal member comprising a roughened portion for jointing to a resin mold in a part of a surface to form a composite, wherein
when the resin mold is jointed to the surface of the metal member in a manner such that the resin mold includes the roughened portion,
in a specific interface region including a joint interface between the roughened portion and the resin mold,
an average volume in a unit area of voids between the roughened portion and the resin mold is 0.05 μm³ or smaller per 1 μm² of a plane generally parallel to the joint interface, and a maximum dimension of the void is 1000 nm or smaller.
